(19) United States
(12) Patent Application Publication
(10) Pub. No.: US 2010/0018580 A1
(43) Pub. Date: Jan. 28, 2010

(54) Method for the Manufacture of a Solar Cell and the Resulting Solar Cell

(75) Inventors: Dirk Habermann, Kirchzarten (DE); Patrik Müller, Reute (CH)

Correspondence Address: AKERMAN SENTERFITT, P.O. BOX 3188, WEST PALM BEACH, FL, 33402-3188, US

(73) Assignee: Schmid Technology Systems GmbH, Niedereschach (DE)

(21) Appl. No.: 12/554,410

(22) Filed: Sep. 4, 2009

Related U.S. Application Data
(63) Continuation of application No. PCT/EP2008/001702, filed on Mar. 4, 2008.

(30) Foreign Application Priority Data
Mar. 8, 2007 (DE) DE 102007012268.5

(51) Int. Cl. H01L 31/00; H01L 31/18

(52) U.S. Cl. 136/261; 438/72; 257/E21.158

(57) ABSTRACT

In a method for the manufacture of a solar cell from a silicon substrate to the front and back surfaces are firstly applied a first antireflection coating with an optical refractive index n between 3.6 and 3.9. To the latter is applied a second antireflection with an optical refractive index n between 1.94 and 2.1. The antireflection coatings are separated down to the underlying silicon substrate in order to introduce metal contacts to the silicon substrate into the antireflection coatings.

### FIELD OF APPLICATION AND PRIOR ART

The invention relates to a method for the manufacture of a solar cell from silicon or a silicon substrate, as well as a solar cell manufactured using such a method.

Normally the efficiency of solar cells is influenced by the nature of the surface of said solar cell or a surface coating. Particular significance is attributed to the antireflection and passivation characteristics, so as to in particular permit a maximum incidence of sunlight into the solar cell. Normally the front surface of a solar cell has an antireflection coating, for example of SiN.

The manufacture of a conventional solar cell involves a sequence of process steps, described in summary form hereinafter. The basis is usually provided by monocrystalline or polycrystalline p—Si wafers, which are surface-textured by means of an etching process in order to improve the absorption properties. In the case of monocrystalline silicon the etching process is carried out with a mixture of sodium or potassium hydroxide solution and isopropyl alcohol. Polycrystalline silicon is etched with a solution of hydrofluoric and nitric acid. Further etching-cleaning sequences are then performed in order to provide an optimum preparation of the surface for the following diffusion process. In said process a p-n junction in silicon is produced by the diffusion of phosphorus to a depth of approximately 0.5 μm. The p-n junction separates the charge carriers formed by light. For producing the p-n junction the wafer is heated to approximately 800° C. to 950° C. in a furnace in the presence of a phosphorus source, usually a gas mixture or an aqueous solution. The phosphorus penetrates the silicon surface. The phosphorus-doped coating is negatively conductive as opposed to the positively conductive boron-doped base. In this process a phosphorus glass is formed on the surface and is removed in the following steps by etching with HF. Subsequently to the silicon surface is applied a roughly 80 nm thick coating, usually comprising SiN:H, in order to reduce reflection and for passivation purposes. Metallic contacts are then applied to the front surface (silver) and back surface (gold or silver). In order to produce a so-called BSF (Back Surface Field), advantageously of aluminum, in said process part of the aluminum applied to the wafer back surface is alloyed into the silicon in the following firing step.

### PROBLEM AND SOLUTION

The problem of the invention is to provide an aforementioned method and a solar cell manufactured therewith enabling the disadvantages of the prior art to be avoided and more particularly to further increase the efficiency of a solar cell.

This problem is solved by a method having the features of claim 1 and a solar cell having the features of claim 19. Advantageous and preferred developments of the invention form the subject matter of the further claims and are explained in greater detail hereinafter. Furthermore, by express reference the wording of the priority application DE 102007012268.5 filed on Mar. 8, 2007 by the same applicant is made into the content of the present description. By express reference the wording of the claims is made into part of the content of the description.

According to the invention to at least one side of a doped silicon substrate, which is therefore already pretreated for the further production of a solar cell, is applied a first coating having an optical refractive index n, which is between 3.5 and 4.0. To said first coating is applied a second coating with an optical refractive index n between 1.9 and 2.2. Thus, within the scope of the present invention a two-layer structure is created for a surface coating of a solar cell or an antireflection coating. This makes it possible to reduce the reflection of light striking the solar cell, so that more light strikes the solar cell and the efficiency of the latter is consequently increased. As a result of such a multilayer structure it is also possible to improve the passivation of the front surface of the solar cell.

According to a development of the invention the first coating can have a refractive index between 3.6 and 3.9. It can comprise or be formed from silicon and/or germanium. It is advantageously formed from a SiGe or a—SiGe:H. Thus, in this case said coating of said material is not used as a semiconductor coating, but instead is intended for an antireflecting function.

In a further development of the invention the second coating can have a refractive index n between 1.94 and 2.1. As a result of such a coating structure a particularly satisfactorily acting, overall antireflection coating is obtained. More-over the second coating can comprise or be formed from silicon, advantageously SiN(x):H.

It is admittedly possible, for example in the case of a solar cell only irradiated on the front surface, to provide such a double coating or layer structure for an antireflection coating solely on the front surface. However, advantageously both sides of the solar cell have such a double layer structure, at least if the two sides are to be irradiated with light.

In a manufacturing method it is possible to firstly coat both sides of the silicon substrate with the first coating. Then the second coating can be applied to both sides, which leads to a process technology that can be handled more readily.

According to a development of the invention the first coating can comprise silicon and germanium, for example the aforementioned compounds. It is possible for at least the first coating and in particular also the second coating or the first coating and second coating together, to have a rising geranium concentration gradient. Such a gradient can be produced during the production or application of the coatings. This makes it possible to positively influence the antireflection characteristics and passivation characteristics.

During further processing of the silicon substrate it is possible at least on one substrate side to partly remove the coatings in order to produce or apply a contact to the underlying doped silicon substrate. Such a contact is advantageously metallic or is made from metal. It can advantageously be linear or lattice-like, but at least on the front surface of the solar cell only takes up a minimum surface area so as to ensure that there is only the minimum shading.

According to a further development of the invention an electrical contact, such as is for example applied as a line contact, is so produced that it is not directly touched by the first coating or does not have any connection therewith. For this purpose the first coating can be separated by a dielectric coating from the electrical contact and such a dielectric coating is for example made from SiN. Advantageously the dielectric coating is formed by the second coating. In an inventive manufacturing method it is possible for the first coating to be applied to the silicon substrate and then structured in such a way that a structural pattern fundamentally corresponds to the shape of the electrical contacts which must be applied. However, it is possible for a structure to be introduced over a somewhat greater surface area or in each case with a somewhat greater width into the coating or the same can be removed. Then the second coating is applied to the first coating and then the second coating is also introduced into the areas which have been correspondingly removed in the first coating in accordance with the structural pattern. Subsequently the second coating is structured with a thinner pattern or is removed down to the underlying silicon substrate in such a way that in the resulting structure the electrical contacts can be introduced with the desired pattern. In this way not only is the inventive layer structure achieved, but simultaneously the electrical contacts do not come into contact with the first coating. Structuring of the coatings can for example take place mechanically, but advantageously lasers are used.

For preparation purposes and prior to the application of the inventive coatings, a top side of the silicon substrate can be n-doped, advantageously with phosphorus. A p-doped coating can be produced on the back surface, which should be thinner and is advantageously doped with or made from aSiGe-boron.

It is possible to provide an above-described, two-layer structure for antireflection and passivation characteristics on both sides of the substrate and an electric, previously described contacting is provided on both sides. A back layer structure is applied to the p-doped silicon.

These and further features can be gathered from the claims, description and drawings and the individual features, both singly or in the form of subcombinations, can be implemented in an embodiment of the invention and in other fields and can represent advantageous, independently protectable constructions for which protection is claimed here. The subdivision of the application into individual sections and the subheadings in no way restrict the general validity of the statements made thereunder.

### DETAILED DESCRIPTION OF THE EMBODIMENTS

Embodiments of the invention are diagrammatically represented in the attached drawings, wherein show:

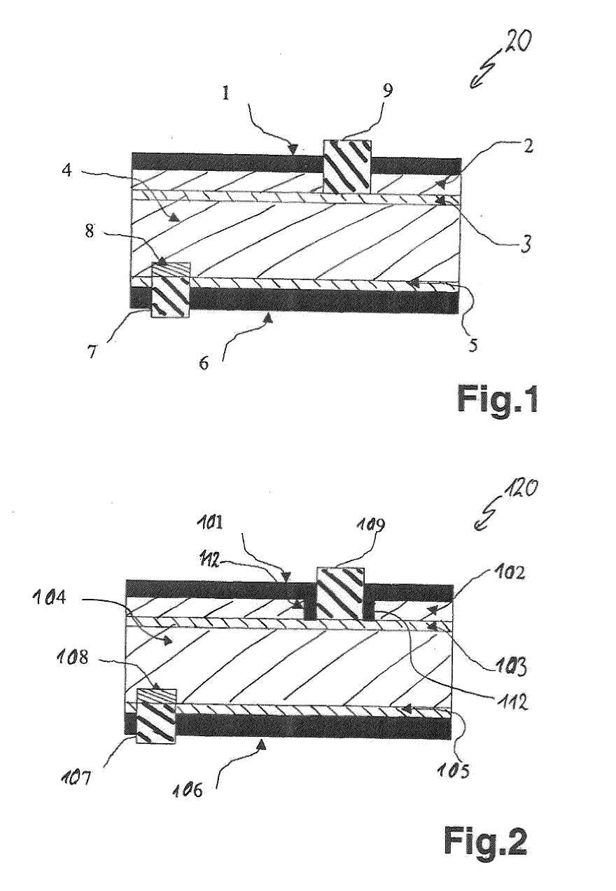

FIG. 1A section through a solar cell with two coatings having different optical refractive indices on both sides, as well as contacts introduced into the same.

FIG. 2 A variant of the solar cell of FIG. 1 with a somewhat modified contact arrangement on the front surface.

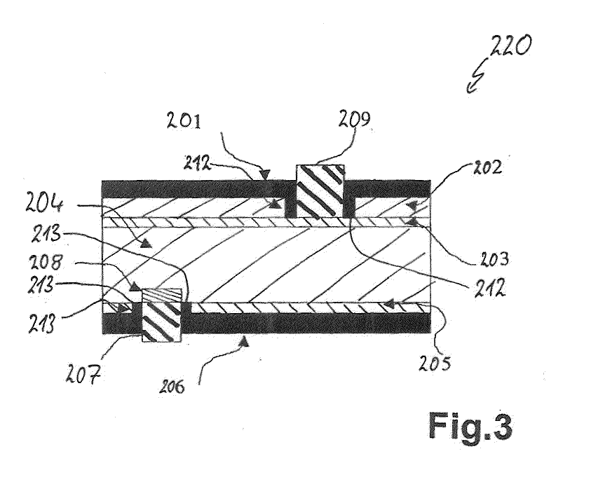

FIG. 3 A further variant of the solar cell of FIG. 1 with a further modified contacting on the front and back surfaces.

### DETAILED DESCRIPTION OF THE EMBODIMENTS

FIG. 1 shows in section a solar cell 20. On a p-doped silicon substrate 4 a thinner coating 3 of phosphorus-doped n-silicon is applied to the upwardly directed front surface. The front, first antireflection coating 2 having an optical refractive index n between 3.6 and 3.9 is applied to the coating 3. To said front, first coating 2 is applied a front, second antireflection coating 1, whose optical refractive index n is between 1.94 and 2.1.

On the back surface of substrate 4 is provided a back, first antireflection coating 5, whose refractive index n corresponds to the front, first antireflection coating 2. On the same is once again provided a back, second antireflection coating 6, whose refractive index n once again corresponds to the front, first antireflection coating 1.

The coating of the substrate 4 or the prior doping has been described in detail hereinbefore. Advantageously to the substrate 4 with the front n-silicon coating 3 is firstly applied the front and back, first antireflection coatings 2 and 5. In a further method step the front and back, second antireflection coatings 1 and 6 are applied.

For the production of the electrical contacts, trenches are made, for example by laser machining, in the front surface or the front, first and second antireflection coatings 1 and 2. Into said trenches are introduced metal contacts 9 in the manner described hereinbefore, for example by printing. Electrical contact 9 is advantageously made from aluminum and also contacts the n-silicon coating 3.

A similar contacting is carried out on the back surface of solar cell 20 and firstly the two back antireflection coatings 5 and 6 are separated down to the substrate 4. In the resulting trenches are introduced a further metallic contact 7 made from aluminum, similar to what was described previously for the front surface. Between the aluminum contact 7 and the substrate 4 of p-doped silicon is formed a so-called aluminum back surface field 8, as is generally known to the expert.

The advantage of the double antireflection coatings 1 and 2 on the front surface, as well as coatings 5 and 6 on the back surface of the solar cell 20 compared with conventional single-layer antireflection coatings, for example of SiN, is the much lower reflectivity, particularly in the wavelength range below 550 nm and above 700 nm. Therefore the light efficiency and therefore also the energy efficiency of the inventive solar cell is significantly improved.

FIG. 2 shows a further solar cell 120 once again constituted by a substrate 104, as described in connection with FIG. 1, which has on its top side a phosphorus-doped, n-silicon coating 103. First antireflection coatings 102 and 105 are applied to the front and back surfaces and to these are once again applied second antireflection coatings 101 and 106. The optical refractive indices can be the same as described relative to FIG. 1.

Whereas on the back surface contacting once again takes place with an aluminum metal contact 107 introduced into a trench in the two back antireflection coatings and with the resulting aluminum back surface field 108, contacting on the front surface is somewhat different. Here in the front, first antireflection coating 102 is made a trench or the latter is only separated to a width which is much larger than the electrical contact 109 to be subsequently applied. The front, second antireflection coating 101 is then applied and in it is formed a further trench or it is separated down to the n-silicon coating 103 over a width corresponding to that of the contact 109. Subsequently the contact 109 is introduced in the manner described hereinbefore. The advantage here is that the metallic contact 109, as described hereinbefore, is only directly connected to the n-silicon coating 103 or contacted therewith, but not with the front, first antireflection coating 102. The portions of the front, second antireflection coating 101 located between the front, first antireflection coating 102 and the metal contact 109, act as a dielectric coating for isolating the front surface contact of solar cell 120.

FIG. 3 shows another variant of a solar cell 220, which in much the same way as in FIG. 2 provides for the formation of the front-surface contacting also on the back surface. This means that between the back-surface, first antireflection coating 205 and the back-applied aluminum metal contacts 207 extends part of the back-surface, second antireflection coating 206 with portions 213 on the back surface of substrate 204. Portions 213 form a dielectric coating for isolating the back-surface metal contact 207 with respect to the back-surface, first antireflection coating 205. Here the aluminum back surface field 208 is once again formed. Otherwise the structure of the solar cell 220 with substrate 204, n-silicon coating 203 and front-surface antireflection coating through the front, first antireflection coating 202 and the front, second antireflection coating 201 with the front surface metal contact 209 corresponds to the structure of FIG. 2 and this also applies to the manufacturing method.

The form of the front and back-surface contacts is always the same in the drawings shown, but can also differ, for example on one side there can be linear contacts and on the other side contact shapes differing therefrom.

As a result of the characteristics of the first antireflection coating, particularly on the front surface, with respect to the underlying silicon substrate it is possible to bring about an optimum adjustment of the optical characteristics. In addition, a very strain-free coating of the silicon substrate is possible.

1. Method for the manufacture of a solar cell from a doped silicon substrate, wherein to at least one side of said doped silicon substrate is applied a first coating with an optical refractive index n between 3.5 and 4.0 and to said first coating is applied a second coating with an optical refractive index n between 1.9 and 2.2.

2. Method according to claim 1, wherein said first coating has a refractive index n between 3.6 and 3.9.

3. Method according to claim 1, wherein said first coating comprises silicon.

4. Method according to claim 1, wherein said first coating comprises germanium.

5. Method according to claim 1, wherein said first coating comprises SiGe and at least said first coating has a rising germanium concentration gradient.

6. Method according to claim 5, wherein said first coating and said second coating together have a rising germanium concentration gradient.

7. Method according to claim 1, wherein said second coating has a refractive index n between 1.94 and 2.1.

8. Method according to claim 1, wherein said second coating comprises silicon.

9. Method according to claim 8, wherein said second coating comprises SiN(x):H.

10. Method according to claim 1, wherein said first coating is firstly applied to both sides of said doped silicon substrate and then said second coating is applied to both sides of said doped silicon substrate.

11. Method according to claim 1, wherein at least on one side of said doped silicon substrate said two coatings are at least partly removed for application of a contact to said underlying doped silicon substrate.

12. Method according to claim 11, wherein at least on one side of said silicon substrate said two coatings are at least partly removed in linear manner.

13. Method according to claim 1, wherein an electrical contact is applied to said doped silicon substrate in such a way that said first coating is not in direct contact with said electrical contact.

14. Method according to claim 13, wherein said first coating is separated by a dielectric coating from said electrical contact.

15. Method according to claim 13, wherein following said application of said first coating, said first coating is structured with a structural pattern corresponding to said electrical contacts to be applied and with a greater width than said electrical contacts, and then said second coating is applied to said first coating and a contact structure is introduced into said first coating with a final pattern of said electrical contacts, wherein subsequently said electrical contacts are introduced into said contact structure.

16. Method according to claim 1, wherein said silicon substrate is n-doped on a top side, wherein on a back surface is produced a p-doped coating.

17. Method according to claim 16, wherein said p-doped coating is thinner than said n-doped coating.

18. Method according to claim 17, wherein said p-doped coating is doped with a—Si:Ge-boron.

19. Solar cell, wherein it is made from a silicon substrate, which is treated using said method according to claim 1.
